(19) United States
(12) Patent Application Publication
(10) Pub. No.: US 2002/0004179 A1
(43) Pub. Date: Jan. 10, 2002

(54) Stacked product of planographic printing plates and stacking method for planographic printing plates

(75) Inventor: Yasushi Nishiyama, Shizuoka-ken (JP)

Correspondence Address: SUGHRUE, MION, ZINN,, MACPEAK & SEAS, PLLC, 2100 Pennsylvania Avenue, N.W. Suite 800, Washington, DC, 20037-3213, US

(73) Assignee: FUJI PHOTO FILM CO., LTD.

(21) Appl. No.: 09/870,625

(22) Filed: Jun. 1, 2001

(30) Foreign Application Priority Data
Jun. 1, 2000 (JP) 2000-165067

(51) Int. Cl. G03F 7/09

(52) U.S. Cl. 430/271.1; 430/523; 206/455

(57) ABSTRACT

A protective member for planographic printing plate is disposed so that a coefficient X of static friction between the protective member for planographic printing plate and an image forming surface is larger than a coefficient Y of static friction between the protective member for planographic printing plate and a non-image forming surface. The protective member slides more with respect to the non-image forming surface than with respect to the image forming surface.

### BACKGROUND OF THE INVENTION

1. Field of the Invention

The present invention relates to a stacked product of planographic printing plates and a stacking method for planographic printing plates. More specifically, the present invention relates to a stacked product of planographic printing plates which is formed by stacking a plurality of planographic printing plates and a protecting member for planographic printing plates, and a stacking method for forming the stacked product of planographic printing plates.

1. Description of the Related Art

In recent years, planographic printing plates such as photosensitive printing plates and thermosensitive printing plates have been widely used in plate-making methods (including electrophotographic plate-making methods) in order to facilitate automation of plate-making processes. Planographic printing plates are generally manufactured in the following manner. On a support such as a sheet-configured or coiled aluminum plate, surface treatments such as graining, anodizing, a silicate treatment, and other chemical conversion treatments are carried out alone or in appropriate combination. Subsequently, processings for applying a photosensitive layer or a thermosensitive layer onto the support and drying the layer are carried out. (Hereinafter, these layers will be collectively referred to as “applied films”, and surfaces of supports with and without an applied film formed thereon are referred to as an “image forming surface” and a “non-image forming surface”, respectively.) Then, the support with the layer applied thereon is cut into a desired size.

The planographic printing plate manufactured in this manner is subjected to plate-making processings such as exposure, development, gum coating, and the like. Subsequently, the planographic printing plate is set in a printing machine, and ink is applied onto the planographic printing plate, thereby printing characters, images, or the like on papers.

In order to protect the applied film of a planographic printing plate, sometimes a sheet of paper called an “interleaf sheet” is made to contact the image forming surface (i.e., the applied film). Particularly, in order to efficiently handle planographic printing plates, a plurality of planographic printing plates may sometimes be stacked in a thickness direction to form a stacked sheaf. In this case, the image forming surface (i.e., the applied film) is often protected by forming a stacked sheaf by, for example, alternatingly stacking the interleaf sheet described above and the planographic printing plate so that the interleaf sheet contacts the image forming surface, and by placing a protective cardboard on an end surface of the planographic printing plate in a stacking direction or placing it on every predetermined number of planographic printing plates.

However, in such a stacked sheaf, the interleaf sheet may be displaced relative to the planographic printing plate due to vibration or the like during transportation or the like of the stacked sheaf. No problem will arise by the displacement as long as it occurs between a non-image forming surface of the planographic printing plate and the interleaf sheet. However, when the displacement occurs between an image forming surface of the planographic printing plate and the interleaf sheet, the interleaf sheet slides with respect to the image forming surface of the planographic printing plate, thereby causing damages to the image forming surface. Therefore, there is a possibility that a blemish which can be seen by naked eyes may be made on the planographic printing plate (defect in appearance), and that problems such as a damage to an image may occur at the time of development (defect in quality).

### SUMMARY OF THE INVENTION

In view of the above-described facts, it is an object of the present invention to obtain a stacked product of planographic printing plates in which an image forming surface of a planographic printing plate can reliably be protected without causing any defect in appearance or in quality of the planographic printing plates, and a method for stacking planographic printing plates for forming the stacked product of planographic printing plates.

In accordance with a first aspect of the present invention, there is provided a product for use in printing, the product comprising: (a) a plurality of planographic printing plates, each planographic printing plate including an image forming surface, and a non-image forming surface opposite the imaging forming surface, the planographic printing plates being arranged in a stack, with adjacent plates in the stack having the imaging forming surface of one of adjacent plates facing the non-imaging forming surface of the other of adjacent plates; and (b) a protective member including opposite surfaces, one surface comprising a coefficient X of static friction with respect to the image forming surfaces of the planographic printing plates, and the other surface comprising a coefficient Y of static friction with respect to the non-image forming surfaces of the planographic printing plates, where X is greater than Y, with the protective member being disposed on at least one of the planographic printing plates in the stack.

That is, in the stacked product of planographic printing plates according to the first aspect, the image forming surface of the planographic printing plate is protected by the protective member for the planographic printing plate.

The protective member for planographic printing plate is disposed so that the coefficient X of static friction between the protective member for planographic printing plate and the image forming surface is larger than the coefficient Y of static friction between the protective member for planographic printing plate and the non-image forming surface. Therefore, the protective member for planographic printing plate slides more with respect to the non-image forming surface than with respect to the image forming surface. With this arrangement, when a force due to vibration or the like acts on the stacked sheaf of planographic printing plates, the protective member for planographic printing plate slides with respect to the non-image forming surface, but it does not slide with respect to the image forming surface. As a result, damage otherwise caused to the applied film by the sliding displacement of the protective member for planographic printing plate relative to the image forming surface can be prevented. In addition, no defect is caused in appearance and in quality of the planographic printing plate.

In the first aspect of the present invention, the coefficient Y of static friction is preferably equal to or less than 93.8% relative to the coefficient X of static friction.

By the coefficient Y of static friction being equal to or less than 93.8% relative to the coefficient X of static friction, sliding of the protective member for planographic printing plate with respect to the image forming surface can be more effectively prevented.

In accordance with a second aspect of the present invention, there is provided a method for forming a stacked product for use in printing, the method comprising the steps of: (a) forming a stack of a plurality of planographic printing plates, wherein each planographic printing plate includes an image forming surface, and a non-image forming surface opposite the imaging forming surface, with adjacent planographic printing plates in the stack having the imaging forming surface of one of adjacent plates facing the non-imaging forming surface of the other of adjacent plates; and (b) disposing a protective member on at least one of the planographic printing plates in the stock, wherein the protective member includes opposite surfaces, one surface including a coefficient X of static friction with respect to the image forming surfaces of the planographic printing plates, and the other surface including a coefficient Y of static friction with respect to the non-image forming surfaces of the planographic printing plates, where X is greater than Y.

That is, in the contacting process, the protective member for planographic printing plate is made to contact the planographic printing plate such that the coefficient X of static friction between the protective member for planographic printing plate and the image forming surface is larger than the coefficient Y of static friction between the protective member for planographic printing plate and the non-image forming surface. Subsequently, in the stacking process, the planographic printing plates which are made contact with the protective member for planographic printing plate are stacked to form a stacked sheaf of planographic printing plates.

In the thus configured stacked sheaf of planographic printing plates, the protective member for planographic printing plate is disposed so that the coefficient X of static friction between the protective member for planographic printing plate and the image forming surface is larger than the coefficient Y of static friction between the protective member for planographic printing plate and the non-image forming surface. Since the protective member for planographic printing plate slides more with respect to the non-image forming surface than with respect to the image forming surface, when a force due to vibration or the like acts on the stacked sheaf of planographic printing plates, the protective member for planographic printing plate does not slide with respect to the image forming surface. As a result, damage otherwise caused to the applied film by the sliding displacement of the protective member for planographic printing plate with respect to the image forming surface can be prevented. In addition, no defect is caused in appearance and in quality of the planographic printing plate.

In addition, with this stacking method for planographic printing plates, since the protective member for planographic printing plate is merely made to contact the planographic printing plate in contact process so that the coefficient X of static friction between the protective member for planographic printing plate and the image forming surface is larger than the coefficient Y of static friction between the protective member for planographic printing plate and the non-image forming surface, a stacked product of planographic printing plates can easily be formed using an existing production line for planographic printing plates.

In the present invention, since a product for use in printing comprises: (a) a plurality of planographic printing plates, each planographic printing plate including an image forming surface, and a non-image forming surface opposite the imaging forming surface, the planographic printing plates being arranged in a stack, with adjacent plates in the stack having the imaging forming surface of one of adjacent plates facing the non-imaging forming surface of the other of adjacent plates; and (b) a protective member including opposite surfaces, one surface comprising a coefficient X of static friction with respect to the image forming surfaces of the planographic printing plates, and the other surface comprising a coefficient Y of static friction with respect to the non-image forming surfaces of the planographic printing plates, where X is greater than Y, with the protective member being disposed on at least one of the planographic printing plates in the stack, damage otherwise caused to the applied film by sliding displacement of the protective member for planographic printing plate with respect to the image forming surface of the planographic printing plate can be prevented. In addition, no defect is caused in appearance and in quality of the planographic printing plate.

In the first aspect of the present invention, since the coefficient Y of static friction is preferably equal to or less than 93.8% relative to the coefficient X of static friction, sliding of the protective member for planographic printing plate with respect to the image forming surface can be more effectively prevented.

In the second aspect of the present invention, since a method for forming a stacked product for use in printing comprises the steps of: (a) forming a stack of a plurality of planographic printing plates, wherein each planographic printing plate includes an image forming surface, and a non-image forming surface opposite the imaging forming surface, with adjacent planographic printing plates in the stack having the imaging forming surface of one of adjacent plates facing the non-imaging forming surface of the other of adjacent plates; and (b) disposing a protective member on at least one of the planographic printing plates in the stock, wherein the protective member includes opposite surfaces, one surface including a coefficient X of static friction with respect to the image forming surfaces of the planographic printing plates, and the other surface including a coefficient Y of static friction with respect to the non-image forming surfaces of the planographic printing plates, where X is greater than Y, a stacked product of planographic printing plates can easily be formed using an existing production line for planographic printing plates without causing any defect in appearance and in quality of the planographic printing plates.

### BRIEF DESCRIPTION OF THE DRAWINGS

FIG. 1 is a perspective view showing a stacked product of planographic printing plates according to an embodiment of the present invention.

FIG. 2 is a perspective view of a stacked product of planographic printing plates according to an embodiment of the present invention, shown in a state in which the stacked product is internally packaged.

FIG. 3 is an explanatory drawing showing coefficients of static friction of the planographic printing plate and the interleaf sheet of the stacked product in a planographic printing plate according to an embodiment of the present invention.

FIG. 4 is a perspective view schematically showing a production line for planographic printing plates to form a stacked product of planographic printing plates according to an embodiment of the present invention.

FIG. 5 is a front view of a stacked product of planographic printing plates used in examples of the present invention.

### DESCRIPTION OF THE PREFERRED EMBODIMENTS

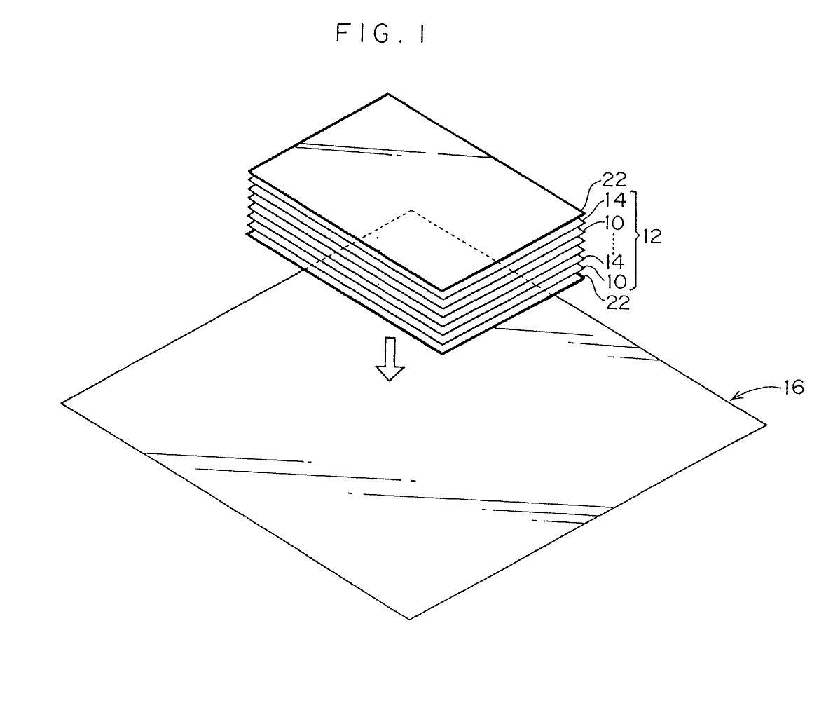

FIG. 1 shows a stacked sheaf 12 of planographic printing plates 10 which includes interleaf sheets 14 (i.e., protective members for planographic printing paper) in accordance with an embodiment of the present invention.

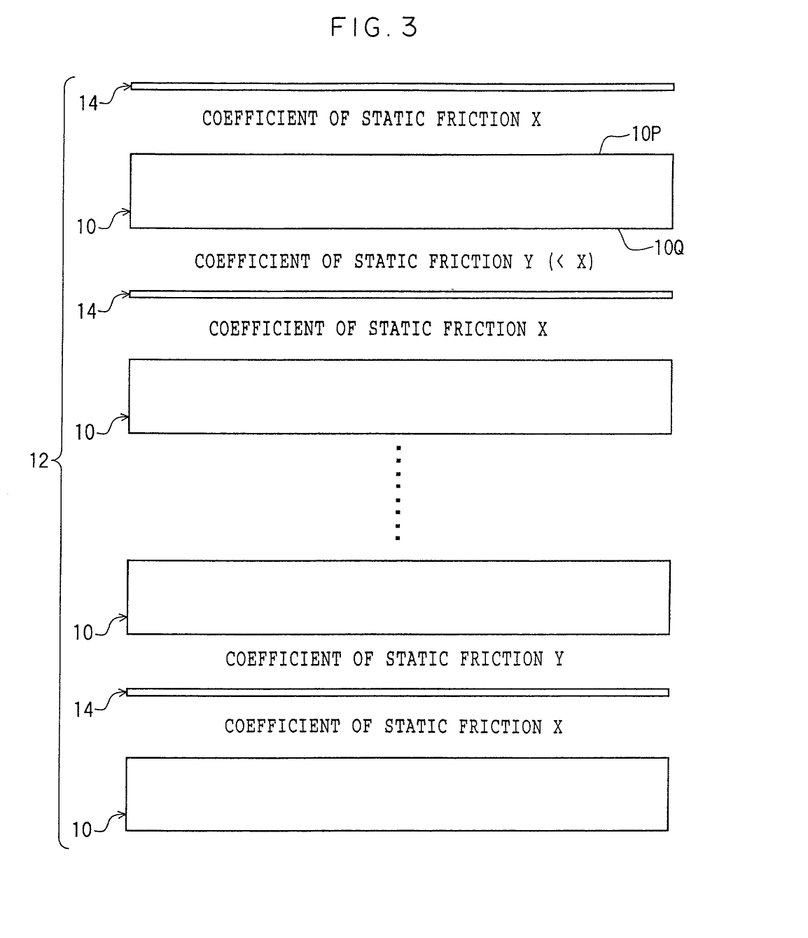

The planographic printing plate 10 is formed by applying a film (a photosensitive layer in the case of a photosensitive printing plate, or a thermosensitive layer in the case of a thermosensitive printing plate) on a thin aluminum support which is formed in a rectangular plate-like configuration. Plate-making processings such as exposure, development, gum coating, and the like are carried out on the applied film of the planographic printing plate 10. Then, the processed planographic printing plate 10 is set in a printing machine, and by applying ink onto the printing plate 10, characters, images, and the like are printed on a paper. Hereinafter, as shown in FIG. 3, the surface of the planographic printing paper 10 with an applied filmapplied thereon is referred to as an image forming surface 10P, while the surface opposite to the image forming surface 10P, i.e., the surface of the planographic printing paper 10 without the applied film applied thereon, is referred to as a non-image forming surface 10Q. Further, the planographic printing plate 10 of the present embodiment is one before the processings (such as exposure, development, and the like) necessary for printing are carried out. The planographic printing plate 10 may be referred to as a planographic printing original plate or a planographic printing plate material as needed.

A specific structure of the planographic printing plate 10 is not limited as long as it has the above-mentioned structure. For example, by manufacturing planographic printing plates for plate printing with a laser in a heat mode system or a photon system, it is possible to provide planographic printing plates which can be made directly from digital data.

Further, the planographic printing plate 10 which can be applied for various plate-making methods can be provided by selecting various components in the photosensitive layer or the thermosensitive layer. Specific examples of the planographic printing plate 10 according to the present invention may include the following (1) to (11).

(1) A planographic printing plate whose photosensitive layer contains a compound which generates acid in the presence of an infrared absorption agent and heat and a compound in which crosslinking is formed by an acid.

(2) A planographic printing plate whose photosensitive layer contains a compound which becomes soluble in alkali in the presence of an infrared absorption agent and heat.

(3) A planographic printing plate whose photosensitive layer is comprised of two layers, i.e., an oxygen cutoff layer and a layer which contains a compound generating a radical by irradiation of a laser beam, a binder which is soluble in alkali, and a multifunctional monomer or prepolymer.

(4) A planographic printing plate whose photosensitive layer is comprised of two layers, i.e., a physical development core layer and a silver halide emulsion layer.

(5) A planographic printing plate whose photosensitive layer is comprised of three layers, i.e., a polymerization layer containing a multifunctional monomer and a multifunctional binder, a layer containing silver halide and a reducing agent, and an oxygen cutoff layer.

(6) A planographic printing plate whose photosensitive layer is comprised of two layers, i.e., a layer containing novolak resin and naphtoquinonediazide, and a layer containing silver halide.

(7) A planographic printing plate whose photosensitive layer contains an organic photoconductor.

(8) A planographic printing plate whose photosensitive layer is comprised of two to three layers, i.e., a laser beam absorbing layer which is removed by irradiation of a laser beam, a lipophilic layer and/or a hydrophilic layer.

(9) A planographic printing plate whose photosensitive layer contains a compound which absorbs energy to generate acid, a high molecular compound which has, at a side chain thereof, a functional group which generates sulphonic acid or carboxylic acid in the presence of an acid, and a compound which imparts energy to an acid generating agent by absorbing visible light.

(10) A planographic printing plate whose photosensitive layer contains a quinondiazide compound and novolak resin.

(11) A planographic printing plate whose photosensitive layer contains a compound which is decomposed by light or ultraviolet light and forms a crosslinking structure in itself or with other molecules within the layer, and a binder which is soluble in alkali.

Particularly, planographic printing plates to which a highly photosensitive film which is exposed by a laser is applied, and thermosensitive planographic printing plates have been used in recent years (for example, the planographic printing plates of the above (1) to (3), and the like). As explained later, when the interleaf sheets 14 of the present embodiment are used, damage to the image forming surface 10P can be reliably prevented.

As can be also seen in FIG. 1, the stacked sheaf 12 of the planographic printing plates 10 is constructed by alternately stacking, in the thickness direction, the planographic printing plate 10 and an interleaf sheet 14 which protects the image forming surface 10P (i.e., the applied film).

Depending on the type and the like of the planographic printing plate 10, a protective cardboard 22 can be disposed on the end surfaces of the stack in a stacking direction (i.e., on the uppermost surface and the lowermost surface of the stack in FIG. 1), or disposed on every predetermined number of the planographic printing plates to prevent blemishes and deformation of the planographic printing plates 10.

The number of the planographic printing plates 10 forming a sheaf 12 is not limited. However, from the viewpoint of efficiency of transportation and storage, the number may be 10 to 100, for example. Further, it is also possible that the sheaf 12 includes a greater number of planographic printing plates 10 so as to transport and store the plates more efficiently (less handling is required). For example, the number of the planographic printing plates 10 may be around 3,000, and the protective cardboard 22 may be disposed on every 20 to 200 sheets of the planographic printing plates 10. Further, the number of the planographic printing plates 10 may be around 1,500, and the protective cardboard 22 may be disposed only on the uppermost surface and the lowermost surface of the stack.

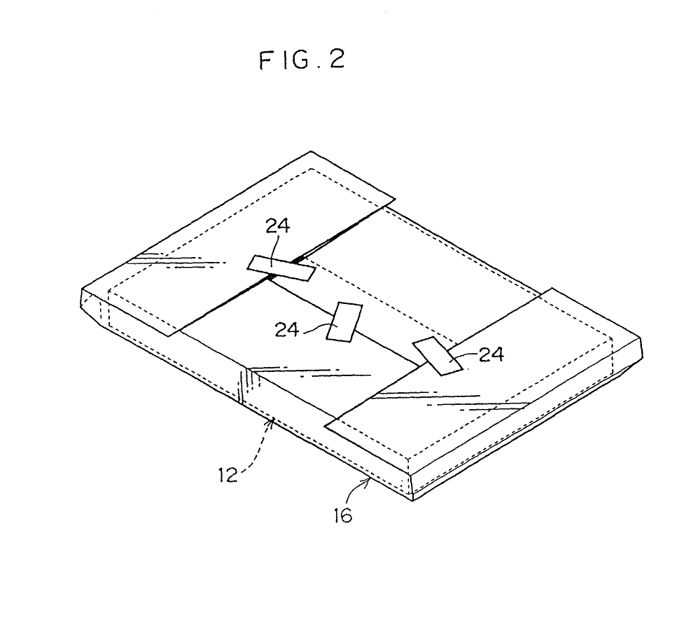

Then, as shown in FIG. 2, the stacked sheaf 12 may be internally packaged in an internal packaging paper 16, and the internal packaging paper 16 may be taped at predetermined positions by the adhesive tape 24. In this way, a packaging structure 18 for the planographic printing plates is formed. Since the internal packaging paper 16 is fastened so as not to spread or slip off inadvertently, the planographic printing plates 10 are reliably shielded from light and kept free from moisture by the internal packaging paper 16. Further, in accordance with the type of planographic printing plates 10, transportation methods, or the like, handling may be further facilitated by further externally packaging the stacked sheaf 12 in an external packaging box such as a corrugated cardboard box and loading the stacked sheaf 12 onto a loading member such as a pallet or a skid. (Materials for the loading member such as paper, resin, metal, and the like are not particularly limited.)

A specific structure of the interleaf sheet 14 is not particularly limited as long as it can protect the image forming surface 10P of the planographic printing plate 10. For example, paper containing 100% of wood pulp, paper not containing 100% of wood pulp but containing synthetic pulp, paper having a low density polyethylene layer formed on the surface of the above papers, and the like may be used. In particular, material cost is decreased for the paper not containing synthetic pulp, and therefore, the interleaf sheets 14 can be manufactured at a low cost. A more specific example of the interleaf sheet 14 is one which is made from bleached kraft pulp and has a basis weight of 30 to 45 g/m², a density of 0.7 to 0.85 g/cm³, a moisture of 4 to 6%, and a PH of 4 to 6. However, the interleaf sheet 14 is not limited to the same.

In the present embodiment, as shown in FIG. 3, considering the surface of the interleaf sheet 14 which is made to contact the image forming surface 10P of the planographic printing plate 10, the Interleaf sheet 14 is disposed so that the coefficient X of static friction between the interleaf sheet 14 and the image forming surface 10P of the planographic printing plate 10 is larger than the coefficient Y of static friction between the interleaf sheet 14 and the non-image forming surface 10Q of the planographic printing plate 10 (i.e., X>Y). For this reason, the interleaf sheet 14 slides more with respect to the non-image forming surface 10Q than with respect to the image forming surface 10P. Generally, smoothness is different in the surface and the back surface of the interleaf sheet 14, since each surface contacts different plate during paper making, and each surface is different in the dry state after paper making (whether or not the surface contacts the roll). For this reason, the coefficient X and the coefficient Y of static friction are different, depending on the surface of the interleaf sheet 14 which is made to contact the image forming surface 10P of the planographic printing plate 10.

When handling the stack sheaf 12 configured as above, the interleaf sheet 12 may be displaced along the surface of the planographic printing plate 10 due to vibration or the like during handling of the stacked sheaf 12. As described above, in the present embodiment, however, since the coefficient X of static friction between the interleaf sheet 14 and the image forming surface 10P of the planographic printing plate is larger than the coefficient Y of static friction between the interleaf sheet 14 and the non-image forming surface 10Q of the planographic printing plate, the interleaf sheet 14 slides more with respect to the non-image forming surface 10Q than with respect to the image forming surface 10P. That is, the interleaf sheet 14 slides with respect to the non-image forming surface 10Q but is prevented from sliding with respect to the image forming surface 10P. Therefore, damage otherwise caused to the applied film by sliding displacement of the interleaf sheet 14 with respect to the image forming surface 10P can be prevented. In addition, no defect is caused in appearance and in quality of the planographic printing plate.

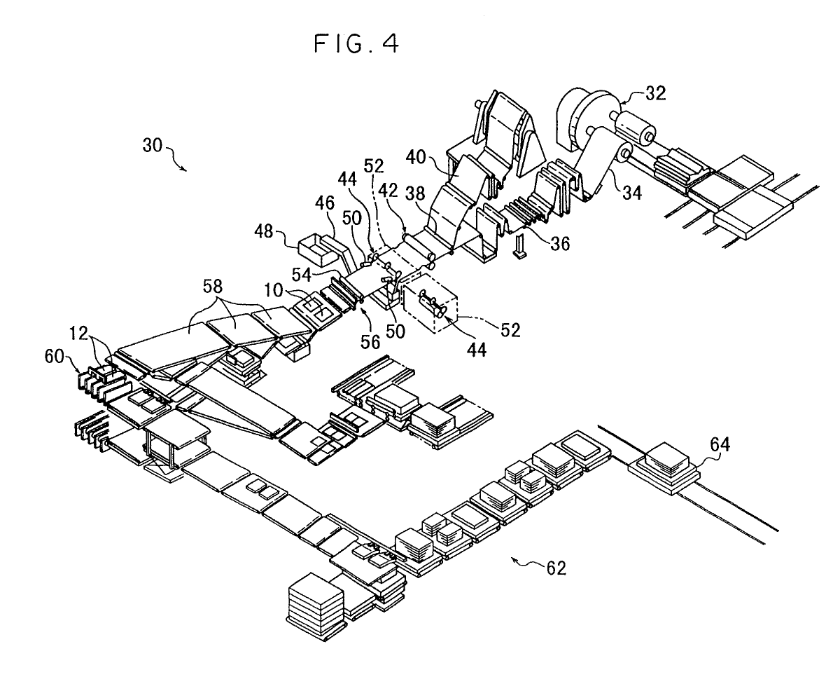

A production line 30 to obtain the planographic printing plate 10 relating to the present invention is shown in FIG. 4.

A feeding mechanism 32, by which a roll-configured web is unwound, is disposed in the upstream side of the production line 30 (upper right side of FIG. 1). The curled elongated web 34 fed out from the feeding mechanism 32 is straightened by a leveler 36 and proceeds to a feeding roller 38. At this time, the interleaf sheet 40, also in the form of a roll, is successively fed out and is adhered to the web 34 (contact process). In this process, the web-like interleaf sheet 40 closely contacts the web 34 and proceeds to a notcher 42.

The notcher 42 provides a punched portion on the web 34 and allows an upper blade of a cutting roller 44 to move toward the transverse direction of the web 34 at the punched portion. With this arrangement, the web 34 and the interleaf sheet 14 can be simultaneously cut in a continuous manner, while the cutting width of the web 34 can be altered.

Debris generated during the cutting process by the cutting roller 44, after being sent to an unillustrated chopper and shredded, is recovered in a recovery box 48 by a recovery conveyor 46. Debris of the interleaf sheet adhered to the debris generated at the cutting process is suctioned by a suction pipe 50.

In the production line 30 of the present embodiment, a cutting unit 52 is formed by a cutting roller 44 and peripheral members (not shown). Further, two cutting units 52 are provided. With this arrangement, set-ups such as replacement of blades or the like can be carried out as to the unused cutting unit 52 which is out of line, thereby making the period of suspension of the production line be minimum.

As described above, the length of the web 34, which has been cut at the predetermined cutting width, in the direction of feeding is detected by a length measuring machine 54. Then the web 34 is cut by a flying shear 56 at a indicated timing. In this manner, a planographic printing plate 10 of a predetermined size is produced.

Next, the planographic printing plate 10 is fed to a accumulating section 60 by a conveyor 58. A stacked sheaf 12 is formed by a predetermined number of stacked planographic printing plates 10 (stacking process). In the accumulating section 60, a protective cardboard 22 (shown in FIG. 1) may be disposed on the uppermost surface and the lowermost surface of the stacked sheaf 12, or on either of them.

Subsequently, the stacked sheaf 12 is stacked on a pallet 64 via a conveying section 62. The stacked sheaf 12 is then proceeded to a store room such as a rack house, or to a packaging process where it is packaged with packaging materials such as tapes, internally packaging materials, externally packaging materials, and the like. Further, it is possible to stack the stacked sheaf 12 on a skid for an automatic plate making machine such as a flat bed skid, a vertical type skid, and the like. Note that, when the stacked sheaf 12 is stacked on these skids for packaging, an accumulating device for accumulating the stacked sheaves 12 on the skid may be provided in the production line 30, thereby enabling direct accumulation of the stacked sheaves 12 in the production line 30.

When the stacked sheaf 12 of the present embodiment is formed in the thus configured production line 30, at the time that the roll-shaped interleaf sheet 14 is sequentially fed out and is adhered to the web 34, an interleaf sheet 14 in a roll form is disposed in a manner in which the coefficient X of static friction between the interleaf sheet 14 and the image forming surface 10P of the planographic printing plate is larger than the coefficient Y of static friction between the interleaf sheet 14 and the non-image forming surface 10Q of the planographic printing plate. Then, the planographic printing plate 10 of the desired size is accumulated in the accumulating section 60, thereby obtaining the stacked sheaf 12 of the present invention. In the present invention, an existing production line 30 of the planographic printing plates 10 can be used without any change, the stacked sheaf 12 of the present invention can be formed easily.

Though, in the above description, the interleaf sheet 14 for protecting the image forming surface 10P is used as an example of the protective member for planographic printing plate, the protective member for planographic printing plate is not limited to the same. For example, in the case in which the protective cardboard 22 is disposed on every predetermined number of planographic printing plates 10 without using the interleaf 14, the protective cardboard 22 is merely disposed so that the coefficient X of static friction between the protective cardboard 22 and the image forming surface 10P of the planographic printing plate is larger than the coefficient Y of static friction between the protective cardboard 22 and the non-image forming surface 10Q of the planographic printing plate. In this case, the protective cardboard 22 functions as the protective member for planographic printing plate of the present invention.

The present invention will be described in detail by Examples hereinafter, but the present invention is not limited to the same.

TABLE 1

| | | Coef- | Coef- | | Defect | |
|---|---|---|---|---|---|---|
| | Used | ficient | ficient | | in | Defect |
| | interleaf | X of static | Y of static | Ratio | appear- | in |
| | sheet | friction | friction | R | ance | quality |
| Comparative | Interleaf | 0.472 | 0.502 | 1.064 | ◯ | X |
| Example 1 | sheet 1 | | | | | |
| Comparative | Interleaf | 0.506 | 0.512 | 1.012 | ◯ | X |
| Example 2 | sheet 2 | | | | | |
| Comparative | Interleaf | 0.422 | 0.488 | 1.156 | Δ | X |
| Example 3 | sheet 2 | | | | | |
| Comparative | Interleaf | 0.473 | 0.510 | 1.078 | ◯ | X |
| Example 4 | sheet 3 | | | | | |
| Example 1 | Interleaf | 0.512 | 0.480 | 0.938 | ◯ | ◯ |
| | sheet 3 | | | | | |
| Example 2 | Interleaf | 0.540 | 0.482 | 0.893 | ◯ | ◯ |
| | sheet 4 | | | | | |
| Example 3 | Interleaf | 0.562 | 0.493 | 0.877 | ◯ | ◯ |
| | sheet 5 | | | | | |

First, the following Interleaf sheets 1 to 5 shown in table 1 were prepared.

Interleaf sheet 1: manufactured by A, a basis weight: 38.5 g/m²

Interleaf sheet 2: manufactured by B, a basis weight: 31.0 g/m²

Interleaf sheet 3: manufactured by B, a basis weight: 35.0 g/m²

Interleaf sheet 4: manufactured by B, a basis weight: 45.0 g/m²

Interleaf sheet 5: manufactured by C, a basis weight: 43.0 g/m²

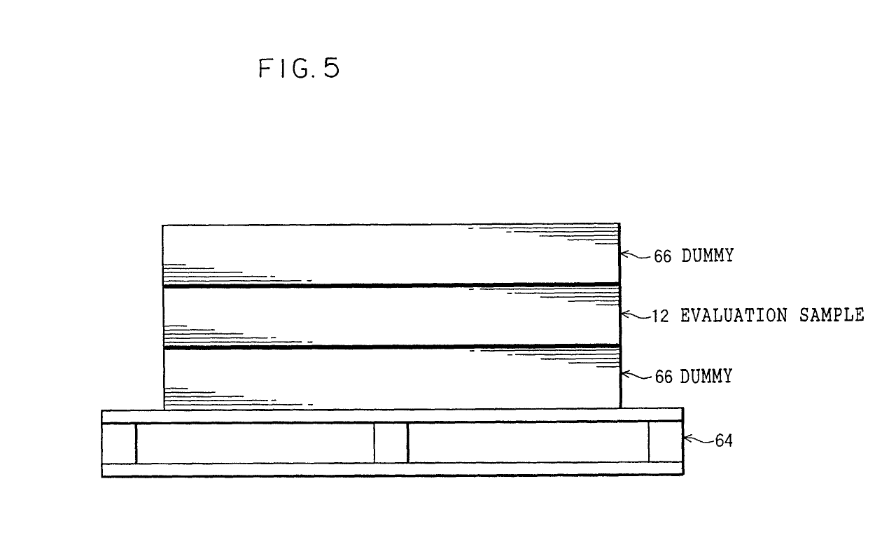

A stacked sheaf 12 as an evaluation sample as shown in FIG. 5 was obtained in the following manner. The interleaf sheets were adhered to the image forming surfaces 10P of the planographic printing plates 10 using the production line 30 shown in FIG. 4. Then 30 sheets of these plates were stacked to form a stacked sheaf 12. In this case, because the value of coefficient X and the value of coefficient Y of static friction become different depending on type of the interleaf sheet, or depending on which surface of the interleaf sheet faces the planographic printing plate, the interleaf sheets in which X<Y were used in Comparative Examples 1 to 4, while the interleaf sheets in which X>Y were used in Examples 1 to 3. Note that, although the same interleaf sheet was used respectively in Comparative Examples 2 and 3, and in Comparative Example 4 and Example 1, the coefficients X and Y were made to be different by reversing the same interleaf sheet. The coefficients X and Y were measured in an inclined type friction measuring machine. The ratio R of the coefficient Y of static friction to the coefficient X of static friction is also shown in Table 1.

As shown in FIG. 5, dummy stack sheaves 66 were disposed above and below the stacked sheaf 12 which is an evaluation sample, and these stack sheaves were then disposed on a pallet 64. The dummy stack sheaf 66 was produced in the following way. Planographic printing plates of the same size as the planographic printing plates 10 forming the stacked sheaf 12 as the evaluation sample were prepared and 30 sheets of these plates were stacked.

The evaluation method was as follows: the pallet 64 on which the stacked sheaves 12 and 66 were disposed was raised as high as 30 cm from the floor using a forklift. The forklift traveled at 10 km/h for 15 meters. A groove having width of 5 cm and depth of 1 cm was formed at the center point of the travel distance (at about 7.5 m from the start point).

After the traveling, the stacked sheaf 12 for evaluation was recovered and the appearance of the planographic printing plate 10 (defect in appearance) was evaluated by the naked eye. Further, development was carried out on the planographic printing plate 10, and the damage to the image on the printing paper after development (defect in quality) was evaluated by the naked eye. In Table 1, ∘ indicates no problem, Δ indicates occurrence of a small problem, and × indicates occurrence of a problem.

As shown in Table 1, no problem occurred in the cases where X>Y (Examples 1 to 3), while defects in quality were caused in each plate in the cases where X<Y (Comparative Examples 1 to 4). In addition, in Comparative Example 3, a small defect also occurred in appearance.

As to the ratio R of the coefficient Y of static friction to the coefficient X of static friction, it has been found that, if the ratio R is at least less than 0.938 (93.8%) as shown in Example 1, no defect occurred in appearance or in quality. The smaller the ratio R becomes, the more the interleaf sheet 14 slides with respect to the non-image forming surface 10Q, and the less with respect to the image forming surface 10P. That is, if the ratio R is small, the defects in appearance or in quality can effectively be prevented. Therefore, the ratio R does not have the substantial lower limit.

What is claimed is:

1. A product of printing plates comprising:
(a) a plurality of planographic printing plates, each planographic printing plate including an image forming surface, and a non-image forming surface opposite the imaging forming surface, the planographic printing plates being arranged in a stack, with adjacent plates in the stack having the imaging forming surface of one of adjacent plates facing the non-imaging forming surface of the other of adjacent plates; and
(b) a protective member including opposite surfaces, one surface comprising a coefficient X of static friction with respect to the image forming surfaces of the planographic printing plates, and the other surface comprising a coefficient Y of static friction with respect to the non-image forming surfaces of the planographic printing plates, where X is greater than Y, with the protective member being disposed on at least one of the planographic printing plates in the stack.

2. The product of claim 1, wherein a plurality of said protective members are included in the stack, with a protective member disposed on one of every 20 to 100 plates of the planographic printing plates in the stack.

3. The product of claim 1, wherein a pair of said protective members are included in the stack, with one protective member disposed on the uppermost surface of the stack and the other protective member disposed on the lowermost surface of the stack, and the stack including up to a total of 1,500 planographic printing plates.

4. The product of claim 1, wherein the ratio of said coefficient Y of static friction to said coefficient X of static friction is up to 93.8%.

5. The product of claim 2, wherein the ratio of said coefficient Y of static friction to said coefficient X of static friction is up to 93.8%.

6. The product of claim 2, wherein said protective member for planographic printing plate comprises an interleaf sheet.

7. The product of claim 3, wherein the ratio of said coefficient Y of static friction to said coefficient X of static friction is up to 93.8%.

8. The product of claim 3, wherein said protective member comprises an interleaf sheet.

9. The product of claim 4, wherein said protective member comprises an interleaf sheet.

10. A method for forming a stacked product for use in printing, the method comprising the steps of:
(a) forming a stack of a plurality of planographic printing plates, wherein each planographic printing plate includes an image forming surface, and a non-image forming surface opposite the imaging forming surface, with adjacent planographic printing plates in the stack having the imaging forming surface of one of adjacent plates facing the non-imaging forming surface of the other of adjacent plates; and
(b) disposing a protective member on at least one of the planographic printing plates in the stock, wherein the protective member includes opposite surfaces, one surface including a coefficient X of static friction with respect to the image forming surfaces of the planographic printing plates, and the other surface including a coefficient Y of static friction with respect to the non-image forming surfaces of the planographic printing plates, where X is greater than Y.

11. The method of claim 10, further comprising the step of preparing the protective member so that the ratio of said coefficient Y of static friction to said coefficient X of static friction is up to 93.8%.

12. The method of claim 10, wherein said step of disposing includes disposing a said protective member on one of every 20 to 100 plates of the planographic printing plates in the stack.

13. The method of claim 10, wherein said step of disposing includes disposing a said protective member on the uppermost surface and the lowermost surface of the stack, wherein the stack includes up to a total of 1,500 planographic printing plates.

14. The method of claim 11, wherein said step of disposing includes disposing a said protective member on one of every 20 to 100 plates of the planographic printing plates in the stack.

15. The method of claim 11, wherein said step of disposing includes disposing a said protective member on the uppermost surface and the lowermost surface of the stack, wherein the stack includes up to a total of 1,500 planographic printing plates.

16. The method of claim 12, wherein said protective member comprises an interleaf sheet.

17. The method of claim 13, wherein said protective member comprises an interleaf sheet.

18. The method of claim 14, wherein said protective member comprises an interleaf sheet.

19. A product for use in printing, the product comprising:
(a) a plurality of planographic printing plates, each planographic printing plate including an image forming surface, and a non-image forming surface opposite the imaging forming surface, the planographic printing plates being arranged in a stack, with adjacent plates in the stack having the imaging forming surface of one of adjacent plates facing the non-imaging forming surface of the other of adjacent plates; and
(b) an interleaf sheet separating each planographic printing plate from the next plate in the stack, each interleaf sheet including opposite surfaces, one surface comprising a coefficient X of static friction with respect to the image forming surfaces of the planographic printing plates, and the other surface comprising a coefficient Y of static friction with respect to the non-image forming surfaces of the planographic printing plates, where X is greater than Y, and each interleaf sheet disposed in the stack with the surface comprising a coefficient X of static friction in contact with the imaging forming surface of a planographic printing plate.

20. The product of claim 19, further comprising a protective member disposed at each end of the stack, wherein the protective member has greater structural strength than a said interleaf sheets.
